(19) United States
(12) Patent Application Publication
(10) Pub. No.: US 2016/0351462 A1
(43) Pub. Date: Dec. 1, 2016

(54) FAN-OUT WAFER LEVEL PACKAGE AND FABRICATION METHOD THEREOF

(71) Applicant: INOTERA MEMORIES, INC., Taoyuan City (TW)

(72) Inventors: Shih-Fan Kuan, Taoyuan City (TW); Neng-Tai Shih, New Taipei City (TW)

(21) Appl. No.: 14/720,844

(22) Filed: May 25, 2015

(51) Int. Cl. H01L 23/31; H01L 23/00

(52) U.S. Cl. CPC H01L 23/3107; H01L 24/05; H01L 2924/3511; H01L 2224/0233

(57) ABSTRACT

A semiconductor package includes a semiconductor die having an active face. At least one pad is disposed on the active face of the semiconductor die. A molding compound seals the semiconductor die except for the active face. The molding compound has a top surface that is flush with the active face of the semiconductor die. A redistribution layer is formed directly on the top surface of the molding compound and on the active face of the semiconductor die. A warpage-control notch is cut into the molding compound. The warpage-control notch is in close proximity to the semiconductor die.

### BACKGROUND OF THE INVENTION

1. Field of the Invention

The present invention relates generally to the field of chip packaging, and more particularly to fan-out wafer level packaging.

2. Description of the Prior Art

Redistributing the bond pads of integrated circuits (“ICs”) in chip packages is becoming increasingly common. In general, the redistribution process converts peripheral wire bond pads on an IC to an area array of solder bumps via a redistribution layer.

The resulting fan-out wafer level packaging may have a larger solder bump bonding area and may be more easily integrated into electronic devices and larger chip packages.

It is known that the backside of the IC is typically covered with a relatively thick layer of the molding compound. The thick layer of the molding compound results in increased warping of the packaging due to coefficient of thermal expansion (CTE) mismatch, and the thickness of the packaging.

Warpage issue is serious especially in a large sized wafer, and has raised an obstacle to a wafer level semiconductor packaging process. Therefore, there remains a need in the art for an improved method of manufacturing fan-out wafer level packages.

### SUMMARY OF THE INVENTION

The present invention is directed to provide an improved semiconductor package that is capable of alleviating or eliminating warpage of a wafer or a package, thereby improving reliability of the semiconductor package.

According to one aspect of the invention, a semiconductor package includes a semiconductor die having an active face. At least one pad is disposed on the active face of the semiconductor die. A molding compound seals the semiconductor die except for the active face. The molding compound has a top surface that is flush with the active face of the semiconductor die. A redistribution layer is formed directly on the top surface of the molding compound and on the active face of the semiconductor die. A warpage-control notch is cut into the molding compound. The warpage-control notch is in close proximity to the semiconductor die.

According to one embodiment of the invention, the redistribution layer redistributes the pad to a fan-out contact pad that is situated beyond an edge of the semiconductor die. The redistribution layer comprises at least one dielectric layer. The dielectric layer fills into the warpage-control notch.

According to another embodiment of the invention, the warpage-control notch is cut into a bottom surface of the molding compound that is opposite to the top surface of the molding compound. The warpage-control notch does not expose the semiconductor die.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIGS. 1-5 are schematic, cross-sectional diagrams showing an exemplary method for fabricating a fan-out wafer level package, wherein:

FIG. 4A shows the warpage-control notches disposed only in the top surface of the molding compound;

FIG. 4B shows the warpage-control notches disposed in both of the top surface and bottom surface of the molding compound;

FIG. 4C shows the warpage-control notches disposed only in the bottom surface of the molding compound;

FIG. 6A depicts scribe line regions and warpage-control notches in the molding compound according to one embodiment of the invention;

FIG. 6B depicts scribe line regions, peripheral ring structure, and warpage-control notches in the molding compound according to another embodiment of the invention;

FIG. 7A˜7C are plan views showing some examples of the warpage-control notches on the bottom surface of the molding compound; and

FIG. 8 to FIG. 10 illustrate an exemplary RDL-first process for fabricating FOWLP according to another embodiment.

### DETAILED DESCRIPTION

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments maybe utilized and structural changes may be made without departing from the scope of the present invention.

The following detailed description is, therefore, not to be taken in a limiting sense, and the scope of the present invention is defined only by the appended claims, along with the full scope of equivalents to which such claims are entitled.

One or more implementations of the present invention will now be described with reference to the attached drawings, wherein like reference numerals are used to refer to like elements throughout, and wherein the illustrated structures are not necessarily drawn to scale. The terms “die”, “semiconductor chip”, and “semiconductor die” are used interchangeable throughout the specification.

FIGS. 1-5 are schematic, cross-sectional diagrams showing an exemplary method (chip-first method) for fabricating a fan-out wafer level package (FOWLP) according to one embodiment of the invention.

As shown in FIG. 1, semiconductor dies 10 are individually positioned on a carrier 4 with their active faces 11 facing down toward the carrier 4. On each of the active faces 11, input/output (I/O) pads 120 may be provided. The rearranged semiconductor dies 10 may be held in position by an adhesive tape 6 of the carrier 4, but not limited thereto.

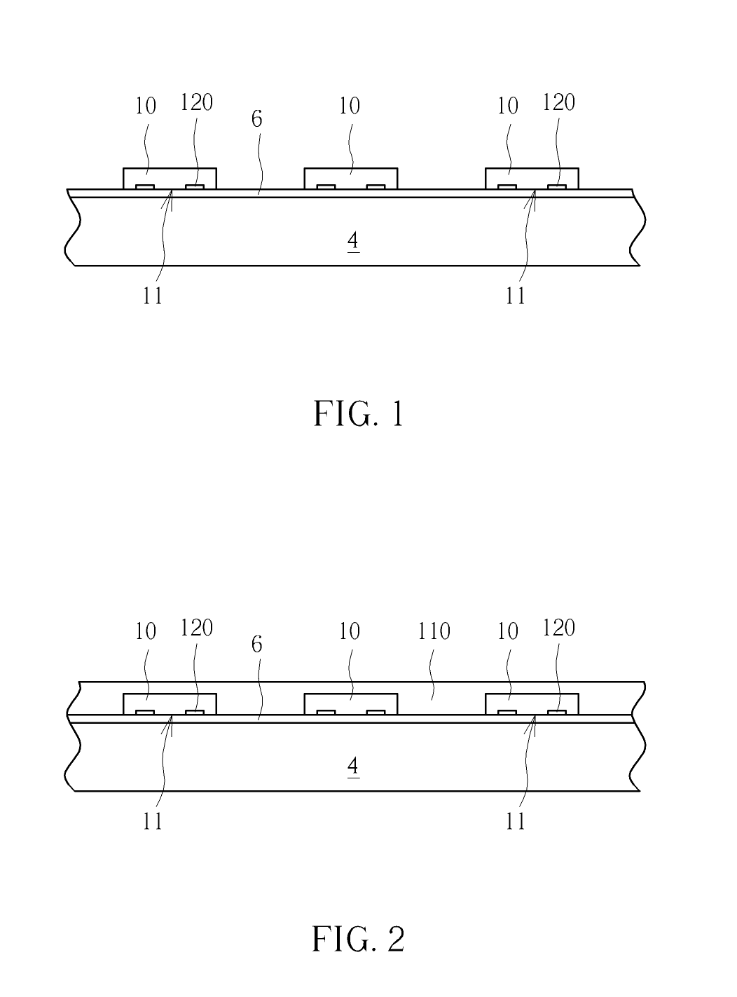

As shown in FIG. 2, a molding compound 110 is then formed over the dies 10. Thereafter, the molding compound 110 may be subjected to a curing process. The molding compound 110 is similar to the epoxy material commonly used to form conventional semiconductor packages.

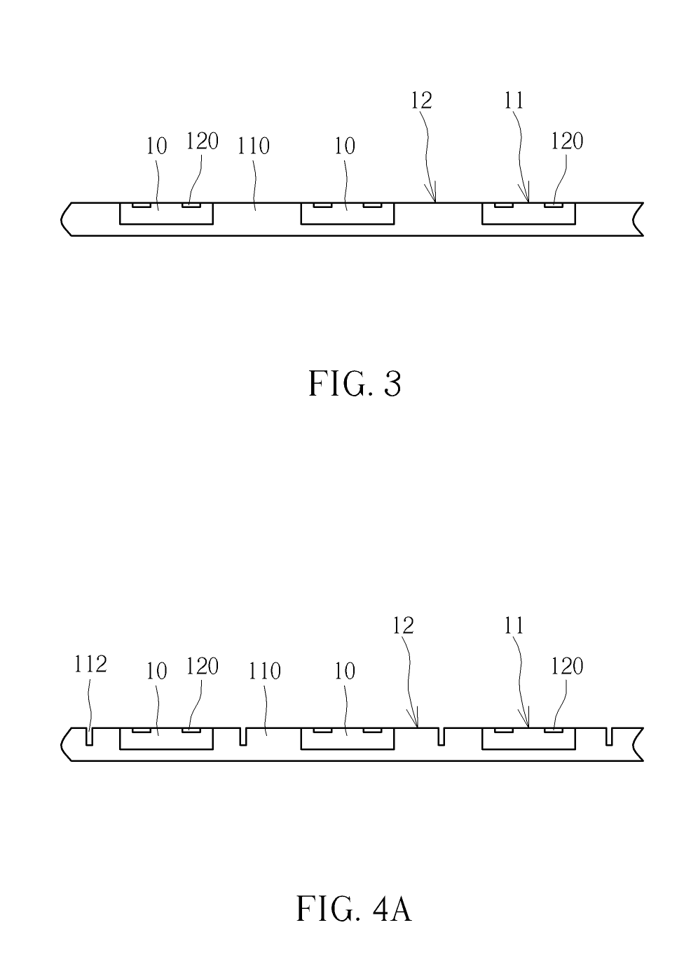

As shown in FIG. 3, after curing, the carrier 4 and tape 6 are removed. A top surface 12 of the molding compound 110 is exposed. At this point, the dies 10 are embedded in the molding compound 110 with the active faces 11 of the dies 10 and I/O pads 120 on the active faces 11 exposed from the top surface 12 of the molding compound 110 for additional connections. According to the illustrated embodiment, the top surface 12 of the molding compound 110 is substantially flush with the active faces 11 of the dies 10.

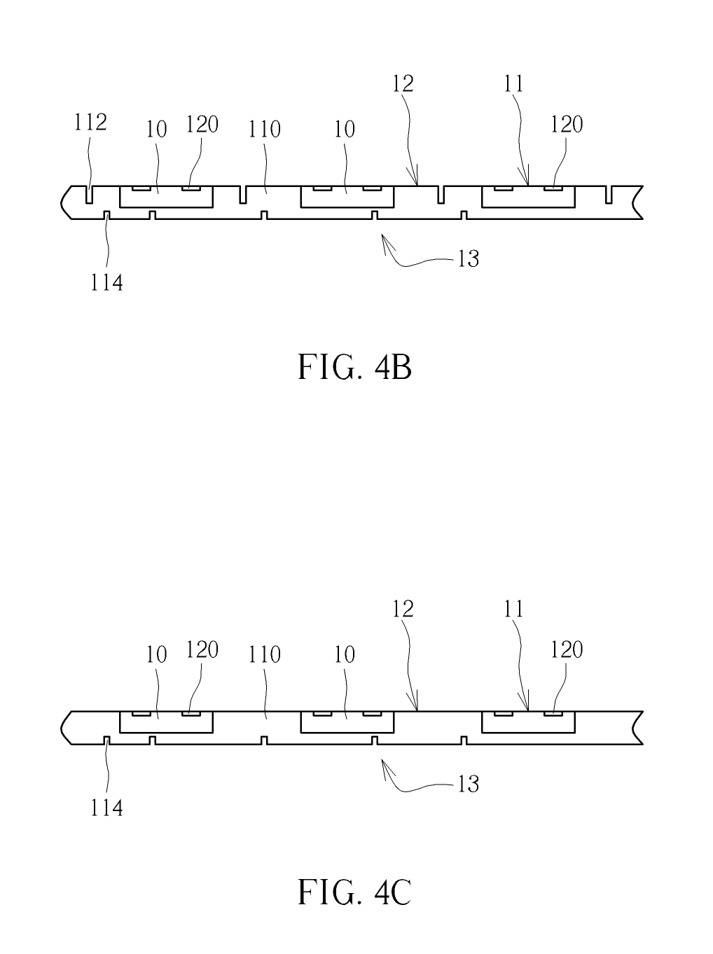

Subsequently, a pre-cutting process is carried out to form a plurality of warpage-control notches 112 in the top surface 12 of the molding compound 110, as shown in FIG. 4A. According to the illustrated embodiment, the warpage-control notches 112 may be formed by using a blade, a saw, or a laser, but not limited thereto. Preferably, the warpage-control notches 112 may have a depth that is smaller than the thickness of the molding compound 110.

The warpage-control notches 112 are able to release the stress that arises due to CTE mismatch so as to alleviate or eliminate warpage of a wafer or a package, thereby improving reliability of the fan-out wafer level package.

According to the illustrated embodiment, the warpage-control notches 112 are formed only within the kerf regions or scribe line regions and are formed only on the top surface 12 of the molding compound 110. It is to be understood that the warpage-control notches 112 may be continuous or discontinuous along their cutting paths.

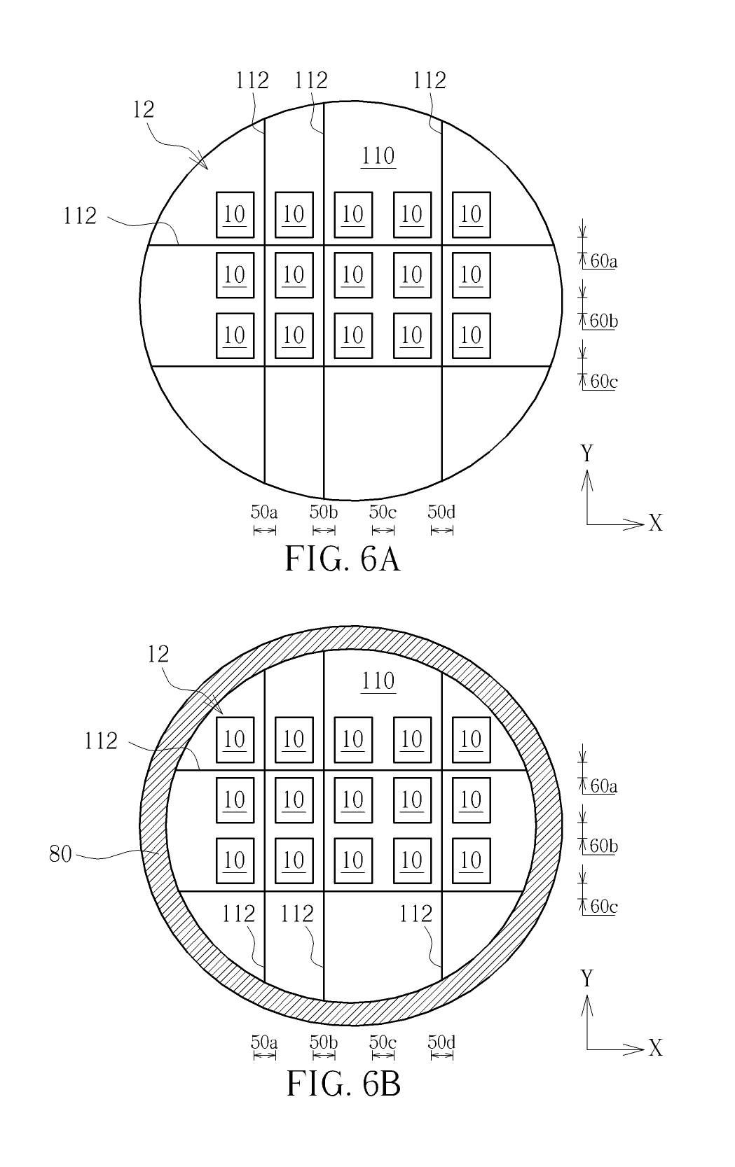

As shown in FIG. 6A, scribe line regions 50a-50d in a first direction (reference x-axis direction) between dies 10 and scribe line regions 60a-60c in a second direction (reference x-axis direction) between dies 10 may be provided. According to the illustrated embodiment, the warpage-control notches 112 in the top surface 12 may not be formed in each and every one of the scribe line regions. For example, in FIG. 6A, only the scribe line regions 50a, 50b, and 50d, and the scribe line regions 60a and 60c are provided with the warpage-control notches 112.

As shown in FIG. 6B, according to another embodiment, a peripheral ring structure 80 is provided. The peripheral ring structure 80 is continuous and annular portion of the molding compound 110 located along the wafer edge. No notch is formed within the peripheral ring structure 80. By providing such peripheral ring structure 80, a better wafer support can be obtained.

According to another embodiment, another pre-cutting process may be carried out to form a plurality of warpage-control notches 114 in the bottom surface 13 of the molding compound 110, as shown in FIG. 4B. In FIG. 4B, it is noteworthy that the warpage-control notches 114 may be formed in an area that is directly under each of the dies 10 as long as the dies 10 are not exposed. Although not specifically indicated, it is to be understood that the warpage-control notches 114 maybe continuous or discontinuous along their cutting paths.

It is to be understood that in still another embodiment only the bottom surface 13 of the molding compound 110 is subjected to the pre-cutting process to form the warpage-control notches 114 in the bottom surface 13 of the molding compound 110, as shown in FIG.

4C.

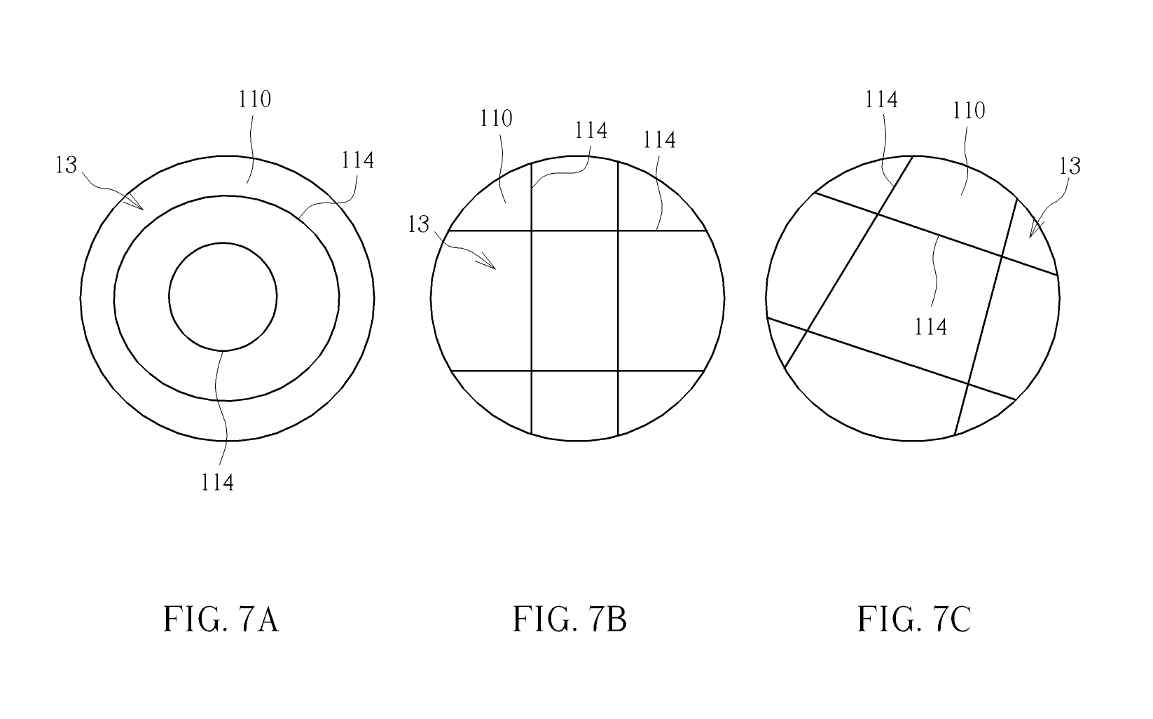

FIGS. 7A˜7C are plan views showing some examples of the warpage-control notches 114 on the bottom surface 13 of the molding compound 110. For example, in FIG. 7A, the warpage-control notches 114 may be arranged in a concentric pattern. For example, in FIG. 7B, the warpage-control notches 114 maybe arranged in an orthogonal and intersecting pattern. For example, in FIG. 7C, the warpage-control notches 114 may be arranged in a non-orthogonal and intersecting pattern.

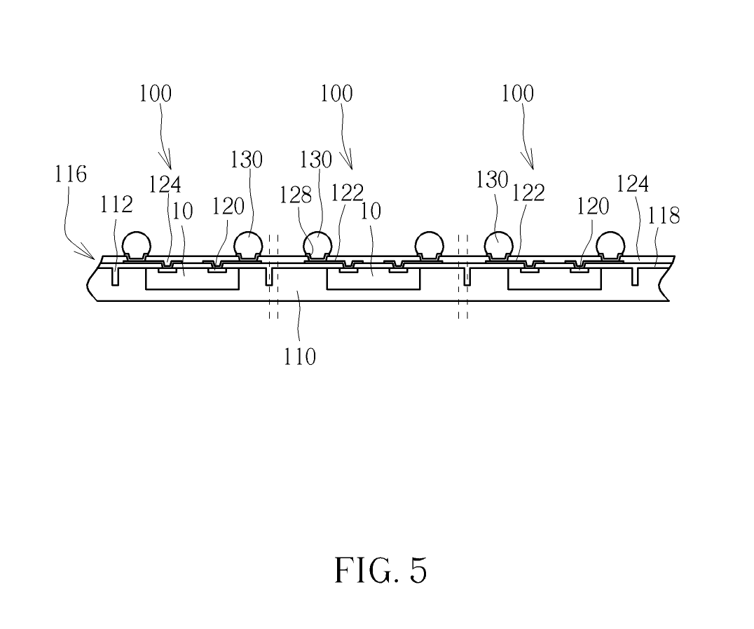

As shown in FIG. 5, after the formation of the warpage-control notches 112/114, a redistribution layer (RDL) 116 is then formed on the molding compound 110. To form the redistribution layer 116, a dielectric layer 118 is first deposited over the top surface 12 and patterned to expose I/O pads 120 of the original dies 10. According to the illustrated embodiment, the dielectric layer 118 may fill into the warpage-control notches 112.

A conductive layer is then deposited and patterned to form electrical traces 122. A second dielectric layer 124 is then deposited and patterned, and another conductive layer is deposited and patterned to form redistributed contact pads 128. Thereafter, solder bumps 130 are formed on the contact pads 128. The molding compound 110 is cut along the scribe line regions as alluded to before, thereby producing individual fan-out wafer level packages 100.

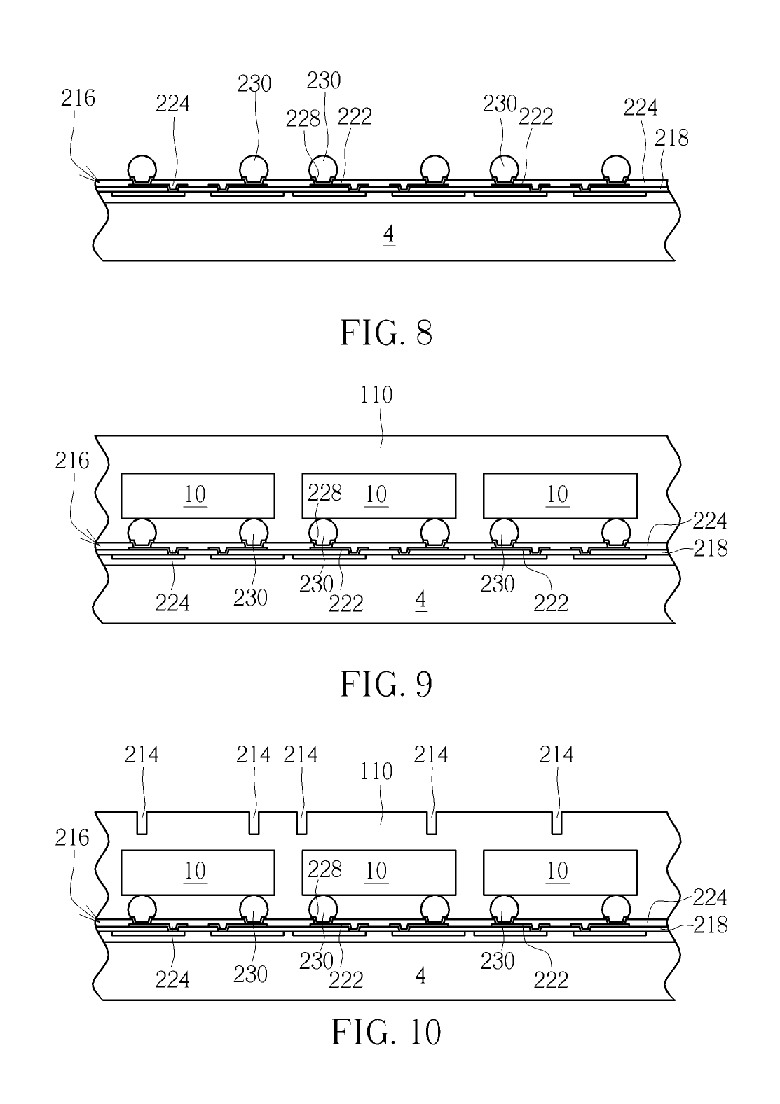

It is to be understood that the present invention may be applicable to a so-called RDL-first process. FIG. 8 to FIG. 10 illustrate an exemplary RDL-first process for fabricating FOWLP according to another embodiment, wherein like numeral numbers designate like regions, layers, or elements.

As shown in FIG. 8, a releasable carrier 4 is provided. A redistribution layer (RDL) 216 is formed on the carrier 4. The RDL 216 may comprise dielectric layers 218 and 224, metal traces 222 and contact pads 228 in the dielectric layers 218 and 224, and bumps (or copper pillars) 230 on the contact pads 228. It is to be understood that the layers of the dielectric and metal traces are for illustration purposes only.

Subsequently, as shown in FIG. 9, flipped dies 10 are mounted on the respective bumps 230 on the RDL 216 with the active faces of the dies 10 face down toward the RDL 216. Thereafter, a molding compound 110 is formed on the RDL 216 and covers the dies 10. Optionally, an underfill (not shown) may be provided between the RDL 216 and the dies 10.

As shown in FIG. 10, after curing, a pre-cutting process is performed to form a plurality of warpage-control notches 214 in an upper surface of the molding compound 110. Subsequently, the carrier 4 is removed to expose a bottom surface of the RDL 216 for further connections. It is to be understood that the pre-cutting process may be performed after the carrier 4 is removed in other embodiments.

Likewise, the warpage-control notches 214 may have a depth that is smaller than the thickness of the molding compound 110. It is noteworthy that the warpage-control notches 214 may be formed in an area that is directly above each of the dies 10 as long as the dies 10 are not exposed. Although not specifically indicated, it is to be understood that the warpage-control notches 214 maybe continuous or discontinuous along the cutting path.

The warpage-control notches 214 are able to release the stress that arises due to CTE mismatch so as to alleviate or eliminate warpage of a wafer or a package, thereby improving reliability of the fan-out wafer level package.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor package, comprising:
a semiconductor die having an active face, wherein at least one pad is disposed on the active face of the semiconductor die;
a molding compound sealing the semiconductor die except for the active face, wherein the molding compound has a top surface that is flush with the active face of the semiconductor die;
a redistribution layer directly on the top surface of the molding compound and on the active face of the semiconductor die;
a first warpage-control notch cut into the top surface of the molding compound, the first warpage-control notch being in close proximity to the semiconductor die, wherein the redistribution layer comprises at least one dielectric layer, and wherein the first warpage-control notch is filled with the dielectric layer of the redistribution layer; and
a plurality of second warpage-control notches cut into a bottom surface of the molding compound that is opposite to the top surface of the molding compound.

2. The semiconductor package according to claim 1, wherein the pad comprises an input/output (I/O) pad.

3. The semiconductor package according to claim 1, wherein the redistribution layer redistributes the pad to a fan-out contact pad that is situated beyond an edge of the semiconductor die.

4-7. (canceled)

8. The semiconductor package according to claim 7, wherein the second warpage-control notches do not expose the semiconductor die.

9. The semiconductor package according to claim 1, wherein the first warpage-control notch is continuous along its cutting path.

10. (canceled)

11. The semiconductor package according to claim 7, wherein the second warpage-control notches are arranged in a concentric pattern, wherein the second warpage-control notches pass through an area that is directly under the semiconductor die and the semiconductor die is not exposed by the second warpage-control notches.

12. The semiconductor package according to claim 7, wherein the second warpage-control notches are arranged in a non-orthogonal and intersecting pattern.
